(19) United States
(12) Patent Application Publication
(10) Pub. No.: US 2004/0166638 A1
(43) Pub. Date: Aug. 26, 2004

(54) Method of forming isolation structures in embedded semiconductor device

(75) Inventor: Byeong Ryeol Lee, Seoul (KR)

Correspondence Address: PILLSBURY WINTHROP, LLP, P.O. BOX 10500, MCLEAN, VA, 22102, US

(73) Assignee: Dongbu Electronics Co. Ltd., Seoul (KR)

(21) Appl. No.: 10/747,621

(22) Filed: Dec. 30, 2003

(30) Foreign Application Priority Data
Dec. 30, 2002 (KR) 10-2002-0087273

(51) Int. Cl. H01L 21/8234

(52) U.S. Cl. 438/275; 438/296; 438/297

(57) ABSTRACT

A method of forming device isolation structures in an embedded semiconductor device is disclosed. The method of forming device isolation structures comprises the steps of: providing a substrate having a first area in which ions are implanted; forming a first device isolation structure through partial oxidation in the first area; forming a first type well with deep junction by diffusing the ions in the first area; forming a second device isolation structure with a trench in a second area of the substrate; forming a first type well with shallow junction in peripheral regions of the second device isolation structure and a region between the first device isolation structure and the second device isolation structure; forming a second type well with shallow junction in peripheral regions of the first device isolation structure and a region of the second device isolation structure; and defining first and second type active regions on the substrate. Therefore, the present invention is applicable to fabrication of semiconductor devices requiring a fine pattern. In addition, the present invention can simplify processes of fabricating semiconductor devices because a well with deep junction is simultaneously formed during formation of the device isolation structures.

### BACKGROUND OF THE INVENTION

1. Field of the Invention

The present invention relates to a method of fabricating a semiconductor device and, more particularly, to a method of forming device isolation structures in an embedded semiconductor device.

2. Background of the Related Art

Among various types of semiconductor devices, there are a semiconductor memory device, which stores data in a memory cell and transfers the data to an external device, and a logic device, which processes the data inputted from the semiconductor memory device and is used for computers and home electronic appliances.

According to high-integration of semiconductor devices, it is required to set up various devices with different functions on a single chip. An example of such a semiconductor device is an embedded semiconductor device where a power device and a logic device are constructed on a single chip. In the embedded semiconductor device, high voltage is applied to an area including the power device and, therefore, devices on the area are isolated by a field oxide which is formed through partial oxidation, i.e., local oxidation of silicon (hereinafter referred to as “LOCOS”). Thus, the embedded semiconductor may employ the field oxide as a device isolation structure.

However, it is not easy to construct a fine pattern structure in the embedded semiconductor device employing the field oxide as a device isolation structure because even an area including the logic device is isolated by means of the field oxide. Thus, an embedded semiconductor device employing such a prior art cannot catch up with a recent trend requiring a design rule less than 0.3 μm.

As a prior art, Korean Patent No. 170728, Kim, discloses an isolating structure of a semiconductor device and a manufacturing method thereof. A method for manufacturing an isolating structure according to the above-mentioned Korean patent comprises the steps of forming a pattern on a semiconductor substrate having a cell region and a peripheral region to expose a nonactivation region; forming a field oxidation layer by oxidizing the exposed portion of the semiconductor substrate using the pattern as a mask; etching simultaneously the field oxidation layer in the cell and peripheral regions until the surface of the cell region is exposed; forming a trench by anisotropically etching the semiconductor substrate of the cell region; and forming an insulating layer on the inner wall of the trench.

### SUMMARY OF THE INVENTION

Accordingly, the present invention is directed to a method of forming isolation structures in an embedded semiconductor device that substantially obviates one or more problems due to limitations and disadvantages of the related art.

An object of the present invention is to provide a method of forming different kinds of device isolation structures on a single chip.

To achieve the object and other advantages and in accordance with the purpose of the invention, as embodied and broadly described herein, the present invention provide a method of forming device isolation structures in an embedded semiconductor device comprising the steps of:

providing a substrate having a first area in which ions are implanted;

forming a first device isolation structure through partial oxidation in the first area;

forming a first type well with deep junction by diffusing the ions in the first area;

forming a second device isolation structure with a trench in a second area of the substrate;

forming a first type well with shallow junction in peripheral regions of the second device isolation structure and a region between the first device isolation structure and the second device isolation structure;

forming a second type well with shallow junction in peripheral regions of the first device isolation structure and a region of the second device isolation structure; and

defining first and second type active regions on the substrate.

The present invention can form both a first device isolation structure by partial oxidation and a second device isolation structure with a trench on a single chip. Therefore, on a single chip, different device isolation structures are employed according to functions of devices formed. Here, the trench has a narrower area than that of the field oxide. Thus, the present invent can embody a design rule less than 0.3 μm in an embedded semiconductor device.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this application, illustrate embodiment(s) of the invention and together with the description serve to explain the principle of the invention. In the drawings;

FIGS. 1 through 13 illustrate, in cross-sectional views, the process steps for forming device isolation structures in an embedded semiconductor device.

### DETAILED DESCRIPTION OF THE PREFERRED EMBODIMENT

The present invention is described in detail. First, a substrate having a first area in which ions are implanted is provided. The first area is defined by a photoresist pattern.

Then, a first device isolation structure is formed in the first area of the substrate by means of partial oxidation. The first device isolation structure is formed by deposition of a pad oxide and a nitride on the substrate and partial oxidation of some part of the substrate exposed through removal of some parts of the pad oxide and the nitride. At the same time, the ions implanted into the substrate are diffused. The partial oxidation is performed through thermal oxidation and heat provided during the thermal oxidation diffuses the ions. Through diffusion of the ions, a first type well with deep junction is formed in the first area of the substrate. The first type well is preferably an n-type well. Therefore, the ions implanted into the first area are preferably n-type ions.

Next, a second device isolation structure having a trench is formed in a second area of the substrate. In detail, a pad oxide and a nitride are deposited on the substrate and a second area of the substrate is exposed through removal of some part of the pad oxide and the nitride. Then, a trench is formed in the exposed substrate and is filled with an insulating material.

Subsequently, a first type well with shallow junction is formed in peripheral regions of the second device isolation structure and a region between the first device isolation structure and the second device isolation structure. The first type well with shallow junction is formed preferably by a high-energy ion implantation. A photoresist pattern is used as a mask for the ion implantation. In addition, the first type well with shallow junction is preferably an n-type well and, therefore, the ions implanted are also preferably n-type ions.

Next, a second type well with shallow junction is formed in peripheral regions of the first device isolation structure and a region in which the second device isolation structure is formed. The second type well is formed by means of an ion implantation using a photoresist pattern as a mask. The second type well is preferably a p-type well because the first type well is an n-type well.

Finally, first and second type active, regions are defined on the substrate. The active regions are defined by an ion implantation on the surface of the substrate except regions including the device isolation structures.

Accordingly, the present invention can construct both a field oxide by partial oxidation and a trench structure on a single chip. In an embedded semiconductor device, an area with a power device can be isolated by the field oxide and an area with a logic device can be isolated by the trench structure. In addition, a well with deep junction can be simultaneously formed during the formation of the device isolation structure by means of partial oxidation and, therefore, the processes can be simplified.

Reference will now be made in detail to the preferred embodiments of the present invention, examples of which are illustrated in the accompanying drawings.

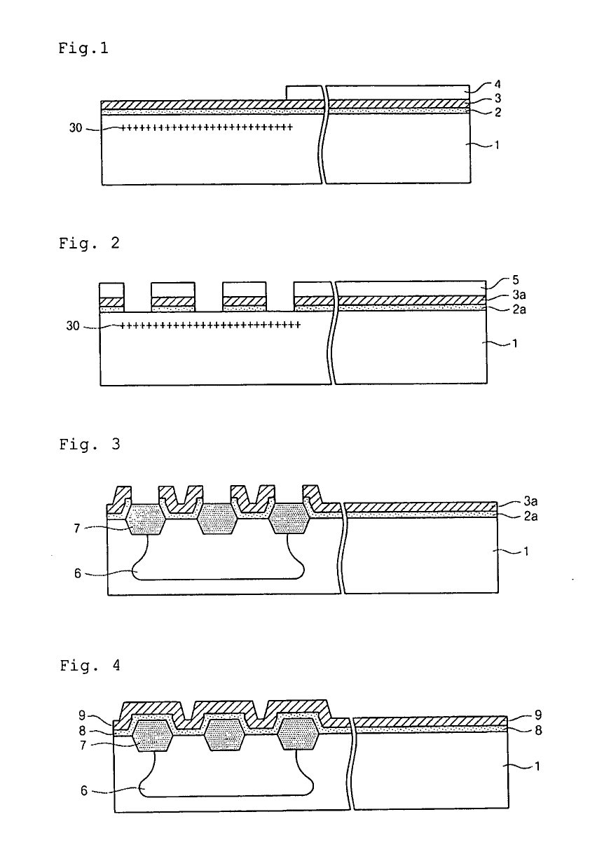

Referring to FIG. 1, a pad oxide 2 and a nitride 3 are deposited on a substrate 1 in sequence. Then, a photoresist layer is deposited on the nitride 3. The photoresist layer is formed by spin-coating using a spin-coater. A photoresist pattern 4 is formed by photolithography. Some part of the nitride for an area for a power device, i.e., a first area is exposed through the photoresist pattern 4. Ion implantation is conducted using the photoresist pattern 4 as a mask to implant ions 30 into the first area of the substrate. The ions implanted are preferably n-type ions. Then, the photoresist pattern 4 is removed by means of stripping or ashing.

Referring to FIG. 2, a photoresist layer is deposited on the nitride 3. A photoresist pattern 5 is formed by photolithography. Some part of the nitride 3 of the first area is exposed through the photoresist pattern 5. The nitride 3 exposed is removed by etching and the pad oxide 2 exposed through the nitride etched is removed by etching. Thus, the nitride 3 and the pad oxide 2 are formed into a nitride pattern 3a and a pad oxide pattern 2a, respectively. The photoresist pattern 5 is removed.

Referring to FIG. 3, the substrate 1 exposed by the nitride pattern 3a and the pad oxide pattern 2a is partially oxidized. The partial oxidation is performed through thermal oxidation at a temperature between 85° C. and 1,000° C. A field oxide 7 is formed in the substrate 1 exposed. At the same time, the ion 30 implanted into the first area of the substrate 1 is diffused. The diffusion of the ion is caused by heat during the thermal oxidation. By diffusion of the ion, an n-well 6 with deep junction is formed in the first area of the substrate 1. Then, the nitride pattern 3a and the pad oxide pattern 2a are removed by means of a wet-etching using phosphoric acid, LAL (low ammonium fluoride liquid) chemical, and so on.

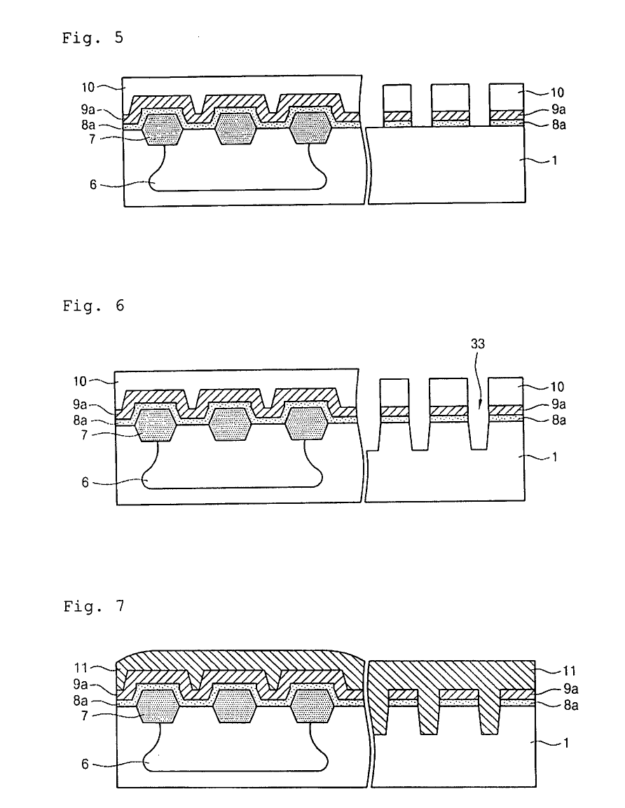

Referring to FIG. 4, a pad oxide 8 and a nitride 9 are deposited in sequence on the substrate 1 having the field oxide 7.

Referring to FIG. 5, a photoresist layer is deposited on the nitride 9. A phtoresist pattern 10 is formed by photolithography. Some part of the nitride 9 is exposed through the photoresist pattern 10. Some parts of the nitride 9 and the pad oxide 8 are removed by etching through the photoresist pattern 10 to form a nitride pattern 9a and a pad oxide pattern 8a. As a result, a second area of the substrate 1 for a logic device is exposed through the nitride pattern 9a and the pad oxide pattern 8a.

Referring to FIG. 6, a trench 33 is formed in the substrate 1 exposed by etching through the photoresist pattern 10. Then, the photoresist pattern 10 is removed.

Referring to FIG. 7, the substrate having the trench 33 is covered with an insulating material to form an insulating layer 11. The insulating layer is preferably an oxide layer. Here, the trench is filled with the insulating material.

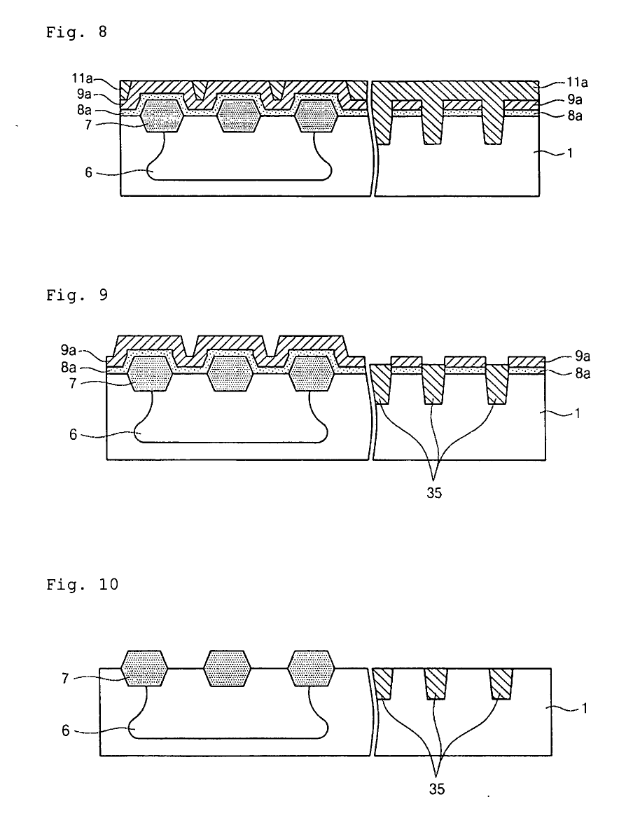

Referring to FIG. 8, the surface of the insulating layer 11 is planarized to form an insulating layer 11a with a flat surface. The planarization is performed preferably through chemical-mechanical polishing until the nitride pattern 9a on the first area including the field oxide 7 is exposed.

Referring to FIG. 9, the insulating layer 11a is removed by a wet-etching or a dry-etching. When the insulating layer 11a is removed, the nitride pattern 9a may be removed a little. As a result, the trench 33 is filled with the insulating material to form a second device isolation structure of a trench oxide 35. In removing the insulating layer 11a, etching is stopped when the nitride pattern 9a is exposed.

Referring to FIG. 10, the nitride pattern 9a and the pad oxide pattern 8a are removed in sequence. Therefore, the field oxide 7 as a first device isolation structure is formed in the first area of the substrate for a power device and the trench oxide 35 as a second device isolation structure is formed in the second area of the substrate for a logic device.

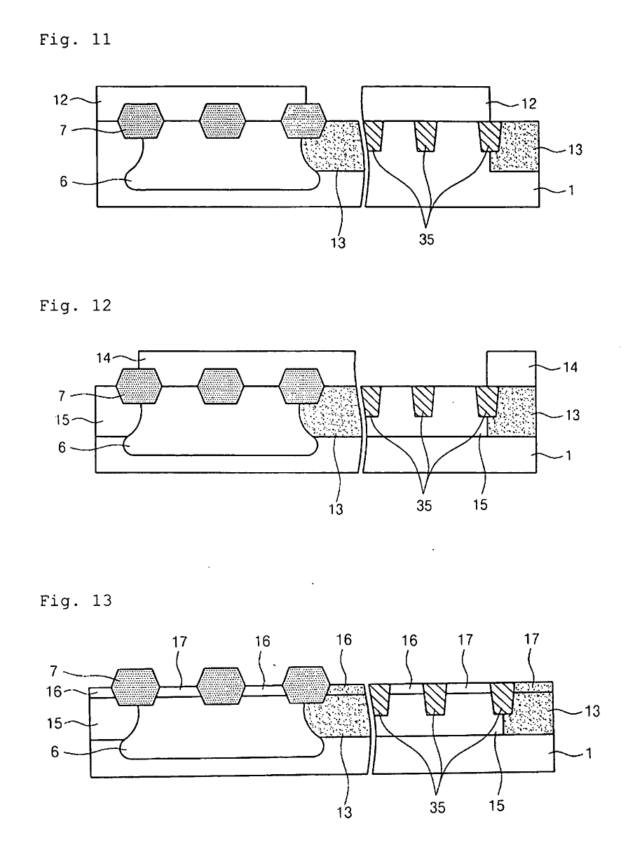

Referring to FIG. 11, a photoresist pattern 12 is formed over the substrate having the first and second device isolation structures. Peripheral regions of the trench oxide 35 and a region between the field oxide 7 and the trench oxide 35 are exposed through the photoresist pattern 12. A high-energy ion implantation is performed using the photoresist pattern 12 as a mask. Ions implanted are preferably n-type. Therefore, an n-well 13 with shallow junction is formed in the substrate 1. The photoresist pattern 12 is removed.

Referring to FIG. 12, a photoresist pattern 14 is formed over the entire surface of the substrate 1. Peripheral regions of the field oxide 7 and a region of the trench oxide 35 are exposed through the photoresist pattern 14. A high-energy ion implantation is performed using the photoresist pattern 14 as a mask. Ions implanted are preferably p-type. Therefore, a p-well 15 with shallow junction is formed in the substrate 1. The photoresist pattern 14 is removed.

Referring to FIG. 13, active regions 16 and 17 are defined over the substrate 1. In other words, some regions except regions in which the field oxide 7 and the trench oxide 35 are formed are defined as active regions 16 and 17. The active regions are formed by means of an ion implantation using the field oxide 7 and the trench oxide 35 as a mask.

Accordingly, the present invention can construct different kinds of device isolation structures on a single chip, thereby employing appropriate device isolation structures according to device features. For example, in an embedded semiconductor device, a power device can be isolated by a field oxide region and a logic device can be isolated by a trench isolation region. Therefore, the present invention is applicable to fabrication of semiconductor devices requiring a fine pattern. In addition, the present invention can simplify processes of fabricating semiconductor devices because a well with deep junction is simultaneously formed during formation of the device isolation structures.

The foregoing embodiments are merely exemplary and are not to be construed as limiting the present invention. The present teachings can be readily applied to other types of apparatuses. The description of the present invention is intended to be illustrative, and not to limit the scope of the claims. Many alternatives, modifications, and variations will be apparent to those skilled in the art.

What is claimed is:

1. A method of forming device isolation structures in an embedded semiconductor device comprising the steps of:
providing a semiconductor substrate having a first area in which ions are implanted;
forming a first device isolation region through partial oxidation in the first area;
forming a first type well with deep junction by diffusing the ions in the first area;
forming a second device isolation region with a trench in a second area of the semiconductor substrate;
forming a first type well with shallow junction in peripheral regions of the second device isolation structure and a region between the first device isolation structure and the second device isolation structure;
forming a second type well with shallow junction in peripheral regions of the first device isolation structure and a region of the second device isolation structure; and
defining first and second type active regions on the semiconductor substrate.

2. The method as defined by claim 1, wherein the diffusion of ions is simultaneously conducted when the partial oxidation is performed.

3. The method as defined by claim 1, wherein the first type well is an n-type well and the second type well is a p-type well.
